(19) United States
(12) Patent Application Publication
(10) Pub. No.: US 2021/0183954 A1
(43) Pub. Date: Jun. 17, 2021

(54) DISPLAY PANEL

(71) Applicant: Shenzhen China Star Optoelectronics Semiconductor Display Technology Co., LTD., Shenzhen, Guangdong Prov. (CN)

(72) Inventor: Xiaoming Liang, Shenzhen, Guangdong Prov. (CN)

(21) Appl. No.: 16/633,306

(22) PCT Filed: Dec. 27, 2019
(86) PCT No.: PCT/CN2019/129205

§ 371 Date: Jan. 23, 2020

(30) Foreign Application Priority Data
Dec. 17, 2019 (CN) 201911304910.8

(51) Int. Cl. H01L 27/32; H01L 51/52

(52) U.S. Cl. CPC H01L 27/322; H01L 51/5275

(57) ABSTRACT

A display panel includes an array substrate including a pixel defining layer, the pixel defining layer defining a plurality of light emitting units distributed in an array; a color filter substrate disposed opposite to the array substrate, wherein the color filter substrate includes a black matrix layer, and the black matrix layer surrounds a plurality of pixel regions distributed in an array corresponding to the light emitting units, the pixel regions include a quantum dot layer and a color filter layer which are arranged in a stack, and include a refractive layer disposed between the quantum dot layer and the color filter layer, and the quantum dot layer is disposed on a side of the color filter substrate near the array substrate.

### FIELD OF INVENTION

The present disclosure relates to the field of display technologies, and more particularly to a display panel.

### BACKGROUND OF INVENTION

With the development of display technology, quantum dot (QD) technology is widely used in display panels because it can improve color saturation of the display panels.

In practical applications, quantum dot color filters use blue light to excite quantum dots to emit red light and green light. However, due to low conversion efficiency of quantum dot color filters for blue light, most of the blue light will be wasted, and a blue light utilization rate is low. In addition, the unconverted blue light can be emitted through the quantum dot color filter, thereby affecting a display performance of the display panel.

### Technical Problem

In the practical application of quantum dot technology, the conversion efficiency of quantum dot color filters for blue light is not high, which will cause most of the blue light to be wasted.

### SUMMARY OF INVENTION

An embodiment of the present application provides a display panel, which can improve a blue light utilization rate.

An embodiment of the present application provides a display panel, comprising an array substrate comprising a pixel defining layer, the pixel defining layer defining a plurality of light emitting units distributed in an array; a color filter substrate disposed opposite to the array substrate, wherein the color filter substrate comprises a black matrix layer, and the black matrix layer surrounds a plurality of pixel regions distributed in an array corresponding to the light emitting units, the pixel regions comprise a quantum dot layer and a color filter layer which are arranged in a stack, and comprise a refractive layer disposed between the quantum dot layer and the color filter layer, and the quantum dot layer is disposed on a side of the color filter substrate near the array substrate.

In an embodiment of the present application, the light emitting units comprise a plurality of blue organic light emitting diodes.

In an embodiment of the present application, the pixel regions comprise a blue light unit, a green light unit, or a red light unit, and the quantum dot layer comprises a first transparent material layer, a green light quantum dot layer, or a red light quantum dot layer, the color filter layer comprises a second transparent material layer, a green light color filter layer, or a red light color filter layer, and the refractive layer comprises a third transparent material layer, a first refractive layer, or a second refractive layer.

In an embodiment of the present application, refractive indices of the first refractive layer and the second refractive layer are greater than or equal to 1, and less than or equal to 1.5.

In an embodiment of the present application, material of the first refractive layer and material of the second refractive layer comprise nitrogen, silicon nitride, or silicon oxide.

In an embodiment of the present application, the blue light unit comprises a first transparent material layer, a second transparent material layer, and a third transparent material layer disposed between the first transparent material layer and the second transparent material layer.

In an embodiment of the present application, the green light unit comprises the green light quantum dot layer and the green light color filter layer, and first refractive layer is disposed between the green light quantum dot layer and the green light color filter layer.

In an embodiment of the present application, the green light quantum dot layer is configured to convert blue light provided by the light emitting units to green light.

In an embodiment of the present application, the green light color filter layer is configured to absorb light sources other than green light.

In an embodiment of the present application, the first refractive layer is configured to cause a part of light sources to be totally reflected at a contact interface between the green quantum dot layer and the first refractive layer.

In an embodiment of the present application, a critical angle of total reflection of a contact interface between the green quantum dot layer and the first refractive layer ranges from 33 degrees to 69 degrees.

In an embodiment of the present application, the red light unit comprises the red light quantum dot layer and the red light color filter layer, and the second refractive layer is disposed between the red light quantum dot layer and the red light color filter layer.

In an embodiment of the present application, the red light quantum dot layer is configured to convert blue light provided by the light emitting units to red light.

In an embodiment of the present application, the red light color filter layer is configured to absorb light sources other than red light.

In an embodiment of the present application, the second refractive layer is configured to cause a part of light sources to be totally reflected at a contact interface between the red quantum dot layer and the second refractive layer.

In an embodiment of the present application, a critical angle of total reflection of a contact interface between the red quantum dot layer and the second refractive layer ranges from 33 degrees to 69 degrees.

In an embodiment of the present application, the color filter substrate further comprises a base substrate, the base substrate is disposed on a side of the color filter substrate away from the array substrate, and a refractive index of the base substrate ranges from 1.5 to 1.6.

In an embodiment of the present application, a critical angle of total reflection of a side of the base substrate away from the array substrate ranges from 26 degrees to 38 degrees.

### Beneficial Effect

From the above, the display panel provided in the embodiment of the present application comprises an array substrate comprising a pixel defining layer, the pixel defining layer defining a plurality of light emitting units distributed in an array; a color filter substrate disposed opposite to the array substrate, wherein the color filter substrate comprises a black matrix layer, and the black matrix layer surrounds a plurality of pixel regions distributed in an array corresponding to the light emitting units, the pixel regions comprise a quantum dot layer and a color filter layer which are arranged in a stack, and comprise a refractive layer disposed between the quantum dot layer and the color filter layer, and the quantum dot layer is disposed on a side of the color filter substrate near the array substrate. In this solution, by setting a refractive layer between the quantum dot layer and the color filter layer in the pixel regions of the color filter substrate, a contact interface between the quantum dot layer and the refractive layer can be totally reflected, thereby improving blue light utilization of the display panel.

### DESCRIPTION OF DRAWINGS

FIG. 1 is a schematic structural diagram of a display panel according to an embodiment of the present application.

FIG. 2 is a schematic diagram of a light propagation path of a display panel according to an embodiment of the present application.

### DETAILED DESCRIPTION OF PREFERRED EMBODIMENTS

The technical solutions in the embodiments of the present application will be clearly and completely described below with reference to the accompanying drawings in the embodiments of the present application. Obviously, the described embodiments are only a part of the embodiments of the present application, but not all the embodiments. Based on the embodiments in the present application, all other embodiments obtained by those skilled in the art without creative efforts fall into the protection scope of the present application.

An embodiment of the present application provides a display panel, which will be described in detail below.

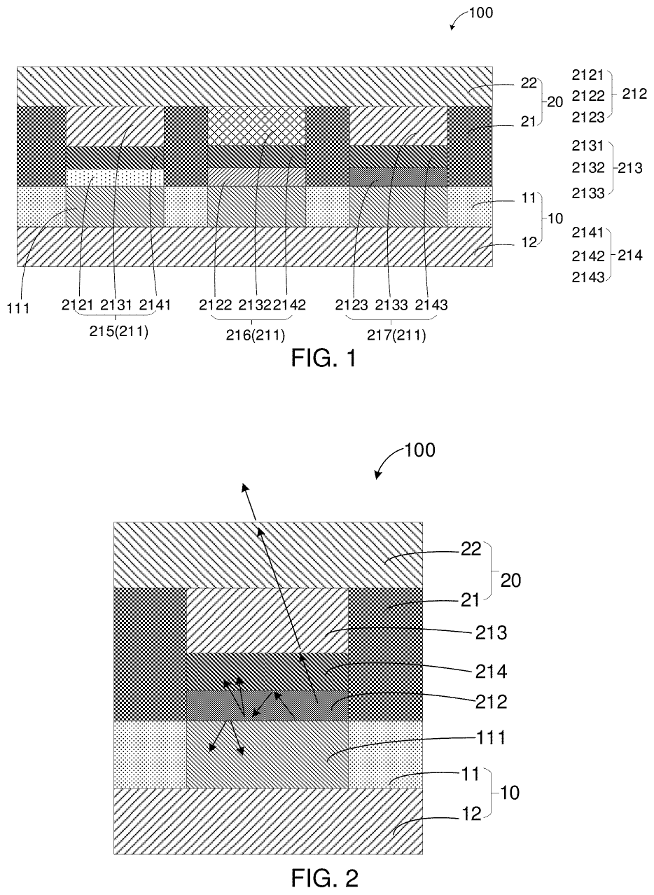

Please refer to FIG. 1, which is a schematic structural diagram of a display panel according to an embodiment of the present application. A display panel 100 may include an array substrate 10 and a color filter substrate 20. It should be noted that the display panel 100 includes, but is not limited to, the above structure. The display panel 100 may further include other structures, such as liquid crystal, a bezel, and the like.

The array substrate 10 may include a pixel defining layer 11 and a base substrate layer 12. The pixel defining layer 11 may define a plurality of light emitting units 111 distributed in an array.

The color filter substrate 20 is disposed opposite to the array substrate 10. The color filter substrate 20 may include a black matrix layer 21 and a base substrate 22. The black matrix layer may be surrounded by a plurality of pixel regions 211 distributed in an array. It should be noted that the pixel regions 211 correspond to the light emitting units 111. It should be noted that the black matrix layer 21 is disposed on a side of the color filter substrate 20 near the array substrate 10.

The pixel regions 211 may include a quantum dot layer 212 and a color filter layer 213. A refractive layer 214 is provided between the quantum dot layer 212 and the color filter layer 213. It should be noted that the quantum dot layer 212 is disposed on a side of the color filter substrate 20 near the array substrate 10.

In some embodiments, the light emitting units 111 may include a plurality of blue organic light emitting diodes. The blue organic light emitting diodes each can be used to provide a blue light source. The pixel regions 211 may include any one of a blue light unit 215, a green light unit 216, or a red light unit 217. The quantum dot layer 212 may include any one of the first transparent material layer 2121, the green light quantum dot layer 2122, or the red light quantum dot layer 2123. The color filter layer 213 may include any one of the second transparent material layer 2131, the green light color filter layer 2132, or the red light color filter layer 2133. The refractive layer 214 may include any one of the third transparent material layer 2141, the first refractive layer 2142, or the second refractive layer 2143.

It should be noted that the first transparent material layer 2121, the second transparent material layer 2131, and the third transparent material layer 2141 are all made of a colorless transparent material. The first transparent material layer 2121, the second transparent material layer 2131, and the third transparent material layer 2141 cannot block or absorb blue light. The blue light can be directly emitted from the base substrate 22 through the first transparent material layer 2121, the second transparent material layer 2131, and the third transparent material layer 2141. It can be understood that the third transparent material layer 2141 is disposed between the first transparent material layer 2121 and the second transparent material layer 2131.

It should be noted that, in the description of this application, the terms “first”, “second”, and “third” are only used for descriptive purposes and cannot be understood as indicating or implying relative importance or implicitly indicating what is indicated number of technical features. Thus, the features defined as “first,” “second,” and “third” may explicitly or implicitly include one or more of the features.

It should be noted that the green light quantum dot layer 2122 can convert blue light, so that blue light is converted into green light. The green light filter layer 2132 is only for green light to pass through. The red quantum dot layer 2123 can convert blue light so that blue light is converted into red light. The red light color filter layer 2133 is only for red light to pass through.

Since the light emitting unit 111 in an embodiment of the present application is a blue light emitting diode, a blue light source can be directly provided. Therefore, in the embodiment of the present application, the blue light unit 215 may be composed of the first transparent material layer 2121, the second transparent material layer 2131, and the third transparent material layer 2141. The blue light can be directly emitted from the base substrate 22 through the first transparent material layer 2121, the second transparent material layer 2131, and the third transparent material layer 2141 to provide a blue display light source for the display panel 100. It can be understood that, since the blue display light source of the display panel 100 can be directly provided by the light emitting unit 111, it is not necessary to perform steps such as conversion. The device structure such as the blue light quantum dot layer and the blue light color filter layer is not needed, and the manufacturing cost of the display panel 100 can be saved.

In some embodiments, in order to reduce manufacturing processes and save human resources, the first transparent material layer 2121, the second transparent material layer 2131, and the third transparent material layer 2141 can be directly integrally molded, and do not need to be manufactured into multiple parts before assembly.

In an embodiment of the present application, the green light unit 216 may convert the blue light emitted by the light emitting unit 111 into green light and emit the green light from the base substrate 22 to provide a green display light source of the display panel 100. Specifically, the blue light emitted by the light emitting unit 111 may be converted into green light by the green light quantum dot layer 2122, and then emitted from the base substrate 22 through the green light color filter layer 2132, thereby providing a blue display light source for the display panel 100. It can be understood that the conversion rate of the green light quantum dot layer 2122 to blue light cannot reach 100%. After passing through the green quantum dot layer 2122, blue light can be divided into green light and part of blue light. If the green light and part of the blue light are directly emitted from the base substrate 22, a display performance of the display panel 100 will be affected. Therefore, in the embodiment of the present application, a green light color filter layer 2132 is provided between the green light quantum dot layer 2122 and the base substrate 22. The green light color filter layer 2132 can absorb light sources other than green light, and only green light can pass through. At this time, the light source emitted from the base substrate 22 through the green light unit 216 is only green light, which can improve the display performance of the display panel 100.

In the embodiment of the present application, the red light unit 217 may convert blue light emitted by the light emitting unit 111 into red light and emit the red light from the base substrate 22 to provide a red display light source of the display panel 100. Specifically, the blue light emitted by the light emitting unit 111 can be converted into red light by the red light quantum dot layer 2123, and then emitted from the base substrate 22 through the red light color filter layer 2133, thereby providing a red display light source for the display panel 100. It can be understood that the conversion rate of the red light quantum dot layer 2123 to blue light is not high. After the blue light passes through the red light quantum dot layer 2123, it can be divided into red light and part of blue. If the red light and a part of the blue light are directly emitted from the base substrate 22, the display performance of the display panel 100 will be affected. Therefore, in the embodiment of the present application, a red light color filter layer 2133 is provided between the red light quantum dot layer 2123 and the base substrate 22. The red light color filter layer 2133 can absorb light sources other than red light, and only red light passes through. At this time, the light source emitted from the base substrate 22 through the red light unit 217 only has green light, which can improve the display performance of the display panel 100.

It can be understood that, due to the green light quantum dot layer 2122 and the red light quantum dot layer 2123, the conversion rate of blue light is not high. Therefore, most of the unconverted blue light will be absorbed by the green light color filter layer 2132 or the red light color filter layer 2133, causing most of the blue light to be wasted, thereby causing the power consumption of the display panel 100 to increase.

In order to solve the above issues, in the embodiment of the present application, a first refractive layer 2142 is provided between the green light quantum dot layer 2122 and the green light color film layer 2132. A second refractive layer 2143 is provided between the red light quantum dot layer 2123 and the red light color film layer 2133. This increases blue light utilization.

Specifically, as shown in FIG. 2, for example, when the blue light emitted by the light emitting unit 111 passes through the green light unit 216, the blue light passes through the green quantum dot layer 2122 to complete light color conversion, and then the green light quantum dot layer 2122 is emitted toward the first refractive layer 2142. Part of the light source may be totally reflected at the contact interface between the green quantum dot layer 2122 and the first refractive layer 2142. The reflected light enters the green light quantum dot layer 2122 again. The unconverted blue light is light-color converted, and then emitted from the green light quantum dot layer 2122. It can be understood that the blue light conversion rate can be increased at this time, thereby improving the blue light utilization rate and saving the power consumption of the display panel 100. It can be understood that when the blue light passes through the red light unit 217, the specific process is the same as that when the blue light passes through the green light unit 216, which will not be described in detail here.

It should be noted that, in an embodiment of the present application, the first refractive layer 2142 and the second refractive layer 2143 may be composed of materials having a refractive index greater than or equal to 1 and less than or equal to 1.5. For example, nitrogen, silicon nitride, or silicon oxide and other inorganic materials with a refractive index of 1, or organic small molecules or organic polymer materials with a refractive index between 1 and 1.5. That is, the refractive indices of the first and second refractive layers 2142 and 2143 are greater than or equal to 1 and less than or equal to 1.5.

In an embodiment of the present application, in order to improve total reflection efficiency of a contact interface of the green light quantum dot layer 2122 and the first refractive layer 2142 or the total reflection efficiency of a contact interface of the red light quantum dot layer 2123 and the second refractive layer 2143, refractive indexes of the green light quantum dot layer 2122 and the red light quantum dot layer 2123 can be adjusted to 1.6 to 1.8. It can be understood that the larger the refractive index difference between the green quantum dot layer 2122 and the first refractive layer 2142 or the red quantum dot layer 2123 and the second refractive layer 2143, the smaller the critical angle at which total reflection occurs. In addition, the critical angle at which the total reflection occurs at the contact interface between the green quantum dot layer 2122 and the first refractive layer 2142 or the contact interface between the red quantum dot layer 2123 and the second refractive layer 2143 ranges from 33 degrees to 69 degrees.

It can be understood that when the light source is emitted from the base substrate 22 of the color filter substrate 20, total reflection will also occur at the contact interface between the base substrate 22 and the air, which will cause loss of the light source to a certain extent.

In order to reduce the loss caused by the light source when total reflection occurs at the contact interface between the base substrate 22 and the air, in the embodiment of the present application, the base substrate 22 may be a glass substrate or a polyimide substrate. In addition, the refractive index of the base substrate 22 ranges from 1.5 to 1.6, and the critical angle at which the contact interface between the base substrate 22 and air is totally reflected is 26 to 38 degrees. That is, the total reflection critical angle of the base substrate 22 away from the array substrate 10 ranges from 26 degrees to 38 degrees.

In addition, for example, when the total reflection critical angle of the contact interface between the substrate 22 and the air is 38°. When the total reflection critical angle of the contact interface between the green quantum dot layer 2122 and the first refractive layer 2142 or the contact interface between the red quantum dot layer 2123 and the second refractive layer 2143 is 38 degrees, the incident angle of the light source converted by the green quantum dot layer 2122 or the red quantum dot layer 2123 at the contact interface between the green quantum dot layer 2122 and the first refractive layer 2142 or the contact interface between the red quantum dot layer 2123 and the second refractive layer 2143 will be less than 38 degrees. This part of the light source will no longer be totally reflected at the contact interface between the base substrate 22 and the air. Thereby, the loss caused by the light source when total reflection occurs at the contact interface between the base substrate 22 and the air is reduced.

From the above, the display panel 100 provided in the embodiment of the present application comprises an array substrate 10 comprising a pixel defining layer 11, the pixel defining layer 11 defining a plurality of light emitting units 111 distributed in an array; a color filter substrate 20 disposed opposite to the array substrate 10, wherein the color filter substrate 20 comprises a black matrix layer 21, and the black matrix layer 21 surrounds a plurality of pixel regions 211 distributed in an array corresponding to the light emitting units 111, the pixel regions 211 comprise a quantum dot layer 212 and a color filter layer 213 which are arranged in a stack, and comprise a refractive layer 214 disposed between the quantum dot layer 212 and the color filter layer 213, and the quantum dot layer 212 is disposed on a side of the color filter substrate 213 near the array substrate 10. In this solution, by setting a refractive layer 214 between the quantum dot layer 212 and the color filter layer 213 in the pixel regions 211 of the color filter substrate 20, a contact interface between the quantum dot layer 212 and the refractive layer 214 can be totally reflected, thereby improving blue light utilization of the display panel 100.

The display panel provided in the embodiments of the present application has been described in detail above. Specific examples are used herein to explain the principles and implementation of this application. The description of the above embodiments is only used to help understand the technical solution of the present application and its core ideas. Those of ordinary skill in the art should understand that they can still modify the technical solutions described in the foregoing embodiments or replace some of the technical features equivalently. These modifications or replacements do not make the essence of the corresponding technical solutions outside the scope of the technical solutions of the embodiments of the present application.

What is claimed is:

1. A display panel, comprising:
an array substrate comprising a pixel defining layer, the pixel defining layer defining a plurality of light emitting units distributed in an array;
a color filter substrate disposed opposite to the array substrate, wherein the color filter substrate comprises a black matrix layer, and the black matrix layer surrounds a plurality of pixel regions distributed in an array corresponding to the light emitting units, the pixel regions comprise a quantum dot layer and a color filter layer which are arranged in a stack, and comprise a refractive layer disposed between the quantum dot layer and the color filter layer, and the quantum dot layer is disposed on a side of the color filter substrate near the array substrate.

2. The display panel according to claim 1, wherein the light emitting units comprise a plurality of blue organic light emitting diodes.

3. The display panel according to claim 2, wherein the pixel regions comprise a blue light unit, a green light unit, or a red light unit, and the quantum dot layer comprises a first transparent material layer, a green light quantum dot layer, or a red light quantum dot layer, the color filter layer comprises a second transparent material layer, a green light color filter layer, or a red light color filter layer, and the refractive layer comprises a third transparent material layer, a first refractive layer, or a second refractive layer.

4. The display panel according to claim 3, wherein refractive indices of the first refractive layer and the second refractive layer are greater than or equal to 1, and less than or equal to 1.5.

5. The display panel according to claim 4, wherein material of the first refractive layer and material of the second refractive layer comprise nitrogen, silicon nitride, or silicon oxide.

6. The display panel according to claim 3, wherein the blue light unit comprises a first transparent material layer, a second transparent material layer, and a third transparent material layer disposed between the first transparent material layer and the second transparent material layer.

7. The display panel according to claim 3, wherein the green light unit comprises the green light quantum dot layer and the green light color filter layer, and first refractive layer is disposed between the green light quantum dot layer and the green light color filter layer.

8. The display panel according to claim 7, wherein the green light quantum dot layer is configured to convert blue light provided by the light emitting units to green light.

9. The display panel according to claim 7, wherein the green light color filter layer is configured to absorb light sources other than green light.

10. The display panel according to claim 7, wherein the first refractive layer is configured to cause a part of light sources to be totally reflected at a contact interface between the green quantum dot layer and the first refractive layer.

11. The display panel according to claim 10, wherein a critical angle of total reflection of a contact interface between the green quantum dot layer and the first refractive layer ranges from 33 degrees to 69 degrees.

12. The display panel according to claim 3, wherein the red light unit comprises the red light quantum dot layer and the red light color filter layer, and the second refractive layer is disposed between the red light quantum dot layer and the red light color filter layer.

13. The display panel according to claim 12, wherein the red light quantum dot layer is configured to convert blue light provided by the light emitting units to red light.

14. The display panel according to claim 12, wherein the red light color filter layer is configured to absorb light sources other than red light.

15. The display panel according to claim 12, wherein the second refractive layer is configured to cause a part of light sources to be totally reflected at a contact interface between the red quantum dot layer and the second refractive layer.

16. The display panel according to claim 15, wherein a critical angle of total reflection of a contact interface between the red quantum dot layer and the second refractive layer ranges from 33 degrees to 69 degrees.

17. The display panel according to claim 1, wherein the color filter substrate further comprises a base substrate, the base substrate is disposed on a side of the color filter substrate away from the array substrate, and a refractive index of the base substrate ranges from 1.5 to 1.6.

18. The display panel according to claim 17, wherein a critical angle of total reflection of a side of the base substrate away from the array substrate ranges from 26 degrees to 38 degrees.
